(19) United States
(12) Patent Application Publication
(10) Pub. No.: US 2024/0047199 A1
(43) Pub. Date: Feb. 8, 2024

(54) SUBSTRATE PROCESSING METHOD

(71) Applicant: ASM IP Holding B.V., Almere (NL)

(72) Inventors: SungHa Choi, Suwon-si (KR); HongSuk Kim, Yongin-si (KR); SangHeon Yong, Yongin-si (KR); JuHyuk Park, Hwaseong-si (KR); KiHun Kim, Yongin-si (KR)

(21) Appl. No.: 18/228,122

(22) Filed: Jul. 31, 2023

Related U.S. Application Data
(60) Provisional application No. 63/394,685, filed on Aug. 3, 2022.

(51) Int. Cl. H01L 21/02; H01J 37/32

(52) U.S. Cl. CPC H01L 21/0234; H01J 37/32357; H01J 37/3244; H01J 37/32165; H01L 21/0217; H01L 21/02164; H01L 21/02219; H01J 2237/332

(57) ABSTRACT

A method of processing a substrate having a gap includes loading the substrate onto a substrate support unit, supplying an oligomeric silicon precursor and a nitrogen-containing gas onto the substrate on the substrate support unit through a gas supply unit, and generating plasma directly in a reaction space by applying a voltage to at least one of the substrate support unit and the gas supply unit, wherein a plurality of sub-steps are performed during the supplying of the oligomeric silicon precursor, the nitrogen-containing gas and the generating a direct plasma, wherein different process parameters are applied during the plurality of sub-steps.

### CROSS-REFERENCE TO RELATED APPLICATIONS

This application claims priority to U.S. Provisional Patent Application Ser. No. 63/394,685 filed Aug. 3, 2022 titled SUBSTRATE PROCESSING METHOD, the disclosure of which is hereby incorporated by reference in its entirety.

### BACKGROUND

### 1. Field

The present disclosure relates to a substrate processing method, and more particularly, to a method of filling a gap formed in a surface of a substrate with a flowable material.

### 2. Description of the Related Art

A gap-fill process is widely used in semiconductor manufacturing processes and refers to a process of filling a gap in a gap structure such as shallow trench isolation (STI) with, for example, an insulating material or a conductive material. In addition, as the degree of integration of semiconductor devices increases, an aspect ratio (A/R) of a gap in a gap structure also increases, and accordingly, it is also difficult to fill the inside of a gap having a high aspect ratio without voids, due to limitations of the known deposition processes.

Chemical vapor deposition (CVD) or plasma chemical vapor deposition (PECVD) is generally used as a deposition technique in a semiconductor manufacturing process, and in such methods, a source gas and a reaction gas are simultaneously supplied into the reaction space to deposit a desired film on a substrate, and thus, there is an advantage in that the film-forming rate is fast. However, when a gap-fill process is performed by using a chemical vapor deposition method for a substrate having gaps with a high aspect ratio on a surface thereof, a film formation rate in an upper region of the gap, that is, near an entrance region of the gap, is relatively higher than a film formation rate in a lower region of the gap, and thus, there is a disadvantage in that the entrance region of the gap is closed first.

FIGS. 1A and 1B are views conceptually illustrating a process in which a void is formed in a gap during a known gap-fill process. Referring to FIG. 1A, a gap structure in which a gap 11 is formed in a substrate 10 is illustrated. For example, when a gap-fill process is performed on the substrate 10 in which the gap 11 is formed by a CVD method, a gap-fill layer 12 is formed on the exposed surface of the substrate 10 having the gap 11. The gap-fill layer 12 is formed relatively uniformly on the bottom and sidewall surfaces of the gap 11 among the exposed surfaces of the gap 11, but the gap-fill layer 12 in an entrance region of the gap 11, that is, the upper region thereof is formed to be relatively thicker than the gap-fill layer 12 in a lower region of the gap 11. That is, as the gap-fill layer 12 is formed to be thicker, a rate at which a width W1 decreases in the upper region of the gap 11 is greater than a rate at which a width W2 decreases in the lower region of the gap 11.

Referring to FIG. 1B, as the gap-fill process is further performed, a thickness of the gap-fill layer 12 in the upper region of the gap 11 gradually increases, and the width W1 in the upper region of the gap 11 gradually decreases. Eventually, when some parts of the gap-fill layer 12 come into contact with each other along the periphery of the gap 11 in the upper region of the gap 11, the upper region of the gap 11 is closed, resulting in formation of a void 14 inside the gap 11. For example, FIG. 2 of Korean Patent Registration No. 898588 illustrates a state in which materials are redeposited and adhered to an opposite sidewall to block an entrance of a gap, resulting in formation of a void.

Therefore, there is a need for a technique for filling a gap without voids in the gap despite an increase in an aspect ratio of the gap in a semiconductor manufacturing process.

### SUMMARY

One of objects to be achieved by the present disclosure is to provide a substrate processing method of filling a gap with a gap-fill layer without voids in the gap during a gap-fill process of a semiconductor manufacturing process.

Another object of the present disclosure is to provide a substrate processing method of forming a flowable silicon nitride film on a substrate.

Another object of the present disclosure is to provide a substrate processing method of filling a gap-fill layer having a uniform film quality across the entire depth of the gap during a gap-fill process.

Additional aspects will be set forth in part in the description which follows and, in part, will be apparent from the description, or may be learned by practice of the presented embodiments of the disclosure.

According to an aspect of embodiments of the technical idea of the present disclosure, a method of processing a substrate having a gap may include loading the substrate onto a substrate support unit, supplying an oligomeric silicon precursor and a nitrogen-containing gas onto the substrate through a gas supply unit on the substrate support unit, and generating plasma directly in a reaction space by applying a voltage to at least one of the substrate support unit and the gas supply unit, wherein a plurality of sub-steps may be performed during supplying of the oligomeric silicon precursor and the nitrogen-containing gas and generating a direct plasma, and different process parameters may be applied during the plurality of sub-steps.

According to an example of the method of processing a substrate, a flowable silicon nitride film may be formed on the substrate during generating a direct plasma.

According to another example of the method of processing a substrate, the method may further include converting the silicon nitride film into a silicon oxide film.

According to another example of the method of processing a substrate, the plurality of sub-steps may be performed at a first temperature and the converting is performed at a second temperature higher than the first temperature.

According to another example of the method of processing a substrate, during the converting, the silicon oxide film may have an oxygen concentration within a preset deviation across a depth of the gap, and the oxygen concentration within the preset deviation may be caused by the plurality of sub-steps to which different process parameters are applied.

According to another example of the method of processing a substrate, the converting may be performed by applying a remote oxygen plasma.

According to another example of the method of processing a substrate, the method may further include densifying the silicon oxide film.

According to another example of the method of processing a substrate, the plurality of sub-steps may be performed at a first temperature, and the densifying may be performed at a third temperature higher than the first temperature.

According to another example of the method of processing a substrate, the plurality of sub-steps may include a first sub-step and a second sub-step subsequent to the first sub-step.

According to another example of the method of processing a substrate, a first process parameter may be set to prevent pores from being formed in a film filling a gap during the first sub-step, and a second process parameter may be set to prevent the film filling the gap from being polymerized during the second sub-step.

According to another example of the method of processing a substrate, a silicon nitride film for filling the gap may be formed during generating a direct plasma.

According to another example of the method of processing a substrate, the silicon nitride film may include a first portion and a second portion on the first portion, and the first portion may be formed by the first sub-step, and the second portion may be formed by the second sub-step.

According to another example of the method of processing a substrate, a first RF power may be applied during the first sub-step, and a second RF power less than the first RF power may be applied during the second sub-step.

According to another example of the method of processing a substrate, argon plasma and helium plasma may be generated during generating a direct plasma, and a ratio of an argon gas to a helium gas during the first sub-step may be less than a ratio of the argon gas to the helium gas during the second sub-step.

According to another example of the method of processing a substrate, the reaction space may be maintained at a first pressure during the first sub-step, and the reaction space may be maintained at a second pressure higher than the first pressure during the second sub-step.

According to another example of the method of processing a substrate, a flow rate of the oligomeric silicon precursor supplied during the first sub-step may be less than a flow rate of the oligomeric silicon precursor supplied during the second sub-step.

According to another example of the method of processing a substrate, a flow rate of the nitrogen-containing gas supplied during the first sub-step may be greater than a flow rate of the nitrogen-containing gas supplied during the second sub-step.

According to another aspect of embodiments of the technical idea of the present disclosure, a method of processing a substrate having a gap formed in a surface of the substrate may include loading the substrate into a reaction space, partially filling the gap by using a direct plasma method, by maintaining the reaction space at a first temperature of less than 100° C. and a first pressure, supplying an oligomeric silicon precursor at a first flow rate in a state in which first RF power is applied, and supplying a nitrogen-containing gas at a first flow rate, additionally filling the gap by using the direct plasma method by maintaining the reaction space at the first temperature and a second pressure higher than the first pressure, supplying an oligomeric silicon precursor at a second flow rate greater than the first flow rate in a state in which second RF power less than the first RF power is applied, and supplying the nitrogen-containing gas at a second flow rate less than the first flow rate, converting a flowable silicon nitride film formed in the gap of the substrate into a silicon oxide film by partially filling the gap and additionally filling the gap by using a remote plasma method, and densifying the silicon oxide film under an oxygen atmosphere.

According to an example of the method of processing a substrate, the converting may be performed at a second temperature higher than the first temperature, and the densifying may be performed at a third temperature higher than the second temperature.

According to another aspect of embodiments of the technical idea of the present disclosure, a method of processing a substrate to fill a gap having a width of 20 nm or less included in the substrate by repeating a cycle may include performing a flowable gap-fill process by applying a direct plasma during the cycle, and changing a process parameter used in the flowable gap-fill process during the cycle.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are views conceptually illustrating a process in which a void is formed in a gap during a general gap-fill process;

FIG. 2 is a flowchart illustrating a substrate processing method according to an example embodiment of the present disclosure;

FIG. 3 is a flowchart schematically illustrating a substrate processing method according to an embodiment of the technical idea of the present disclosure;

FIG. 4 is a flowchart schematically illustrating a substrate processing method according to an embodiment of the technical idea of the present disclosure;

FIG. 5A illustrates a molecular structure of dimer-trisilylamine (TSA) in which two monomer-TSAs are bonded to each other, and FIG. 5B illustrates a molecular structure of trimer-TSA to which three monomer-TSAs are bonded to each other or monomer-TSA is bonded to dimer-TSA;

FIG. 6 is a diagram illustrating an example of a molecular structure reaction formula applicable to a substrate processing method, according to an example embodiment of the present disclosure;

FIGS. 7A to 7G are cross-sectional views illustrating a process sequence in gap-fill process according to example embodiments of the technical idea of the present disclosure;

FIG. 8 illustrates exemplary process parameters for performing the gap-fill processes of FIGS. 7A-7G;

FIG. 9 schematically illustrates a substrate processing apparatus according to an embodiment of the technical idea of the present disclosure;

FIG. 10 is a flowchart schematically illustrating a substrate processing method by using a substrate processing apparatus;

FIG. 11 illustrates a transmission electron microscope (TEM) image comparing a size of respective critical dimension (CD) after performing a single-step deposition on patterns having various CDs, according to the related art;

FIG. 12 illustrates a TEM image in a case in which pores are generated in the entire pattern when deposition is performed on a pattern having a narrow CD size, according to the related art;

FIG. 13 illustrates a TEM image when a seam or a void is generated due to a polymerization phenomenon occurring in an upper region of a gap, according to the related art;

FIG. 14 illustrates an element concentration of a silicon oxide film filling a gap depending on a depth of the gap in the related art;

FIG. 15 illustrates a deposition process which is divided into two or more steps and to which changed parameters are applied;

FIG. 16 illustrates a TEM image when deposition according to the present disclosure is performed on a pattern having a narrow CD size, according to the present disclosure; and

FIG. 17 illustrates an element concentration of a silicon oxide film depending on a depth of a gap in the present disclosure.

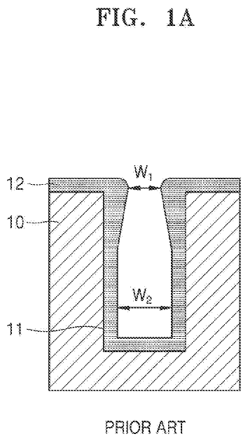

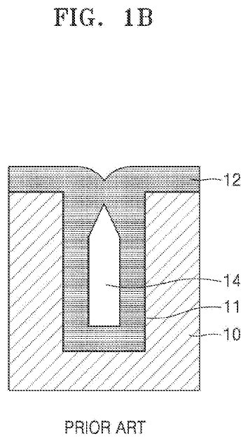

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the present disclosure will be described with reference to the accompanying drawings.

The embodiments of the present disclosure are provided to those skilled in the art to more completely describe the present disclosure, and the following embodiments may be modified in various other forms, and the scope of the present disclosure is not limited to the following embodiments. The embodiments are provided to more fully and completely describe the present disclosure and to fully transfer the idea of the present disclosure to those skilled in the art.

Terminologies used herein are used to describe specific embodiments and are not to limit the present disclosure. As used herein, a singular form may include a plural form unless the context clearly dictates otherwise. In addition, “comprise” and “comprising” used herein specify shapes, numbers, steps, operations, members, elements, and/or presence of groups thereof, which are described, and do not exclude one or more other shapes, numbers, operations, members, elements, and/or addition or presence of groups. As used herein, a term “and/or” includes any one of one listed items and any one or more of all combinations.

Although terms, such as first and second, are used herein to describe various members, regions, and/or regions, the members, components, regions, layers, and/or portions are not limited by the terms. The terms do not indicate a specific order, high and low, or superiority or inferiority and are used only to distinguish one member, one region, or one portion from another member, another region, or another portion. Accordingly, a first member, a first region, or a first portion described below may refer to a second member, a second region, or a second portion without departing from teachings of the present disclosure.

In the present disclosure, “gas” may include evaporated solid and/or liquid and may be composed of a single gas or a mixture of gases. In the present disclosure, a process gas introduced into a reaction chamber through a showerhead may include a precursor gas and an additive gas. The precursor gas and the additive gas may be typically introduced into a reaction space as a mixed gas or separately. The precursor gas may be introduced together with a carrier gas such as an inert gas. The additive gas may include a reactant gas and a diluent gas such as an inert gas. The reactant gas and the diluent gas may be introduced into a reaction space separately. The precursor may be composed of two or more precursors, and the reactant gas may be composed of two or more reactant gases. The precursor is a gas chemisorbed on a substrate and typically containing a metalloid or metal element constituting a main structure of a matrix of a dielectric film, and the reactant gas for deposition reacts with the precursor chemisorbed on the substrate when the gas is excited to immobilize an atomic layer or a monolayer onto the substrate. “Chemisorption” refers to chemical saturation adsorption. A gas other than the process gas, that is, a gas introduced without passing through a showerhead may be used to seal a reaction space, which includes a seal gas such as an inert gas. In some embodiments, a “film” refers to a layer continuously extending in a direction perpendicular to a thickness direction substantially free of pinholes to cover the entire target or a related surface, or simply refers to a layer covering a target or a related surface. In some embodiments, a “layer” refers to a structure having any thickness formed on a surface, a synonym of a film, or a non-film structure. The film or the layer may be composed of a single discontinuous film or layer, or multiple films or layers, having certain properties, and a boundary between adjacent films or layers may or may not be clear, and the film or layer may be established based on physical, chemical, and/or some other properties, formation processes or sequence, and/or functions or purposes of adjacent films or layers.

In the present disclosure, an expression “containing Si—N bonds” may be referred to as having a main structure substantially constituted by the Si—N bond or Si—N bonds, and/or having a substituent substantially constituted by the Si—N bond or Si—N bonds, and being characterized by an Si—N bond or Si—N bonds. A silicon nitride layer may include a dielectric layer including Si—N bonds and may include a silicon nitride layer (SiN) and a silicon oxynitride layer (SiON).

In the present disclosure, an expression “same material” should be construed to mean that the main constituents are the same. For example, when a first layer and a second layer are both silicon nitride layers and are formed of the same material, the first layer may be selected from a group including Si₂N, SiN, Si₃N₄, and Si₂N₃, and the second layer may also be selected from the above group, but specific quality of the second layer may be different from quality of the first layer.

Additionally, in the present disclosure, any two variables may constitute an executable range of the variables in that the executable range may be determined based on a routine operation, and any indicated range may include or exclude endpoints. Additionally, values of any indicated variables (whether the values are indicated as “about”) may refer to exact values or approximate values, include equivalents, and refer to an average value, a median value, a representative value, a majority value, and so on in some embodiments.

In the present disclosure in which conditions and/or structures are not specified, a person skilled in the art may readily provide such conditions and/or structures in light of the present disclosure as a matter of routine experimentation. In all disclosed embodiments, any component used in one embodiment may include components explicitly, necessarily, or essentially disclosed herein for its intended purpose and may be replaced with any component equivalent thereto. Furthermore, the present disclosure is equally applicable to devices and methods.

Hereinafter, description will be made with reference to drawings schematically illustrating embodiments according to the technical idea of the present disclosure. In the drawings, modifications of the illustrated shapes may be expected according to, for example, manufacturing technologies and/or tolerances. Therefore, embodiments of the present disclosure should not be construed as limited to the specific shape of the region illustrated herein and should include, for example, a change in shapes caused by manufacturing.

Hereinafter, embodiments of the present disclosure will be described with reference to the drawings schematically illustrating ideal embodiments of the present disclosure. In the drawings, the illustrated shapes may change depending on, for example, manufacturing techniques and/or tolerances. Therefore, embodiments of the present disclosure should not be construed as limited to the specific shape of the region illustrated herein and should include, for example, a change in shape caused by manufacturing.

First, a substrate processing method of forming a flowable film, for example, a silicon nitride film, on a substrate, according to example embodiments of the present disclosure will be described.

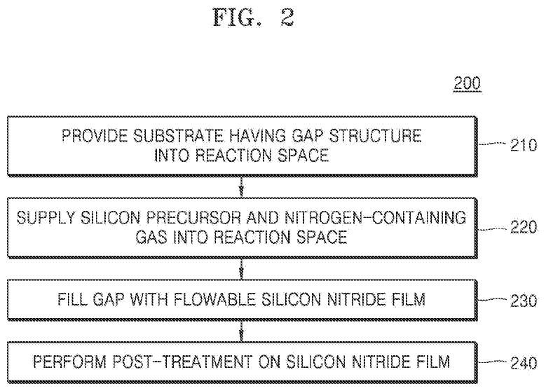

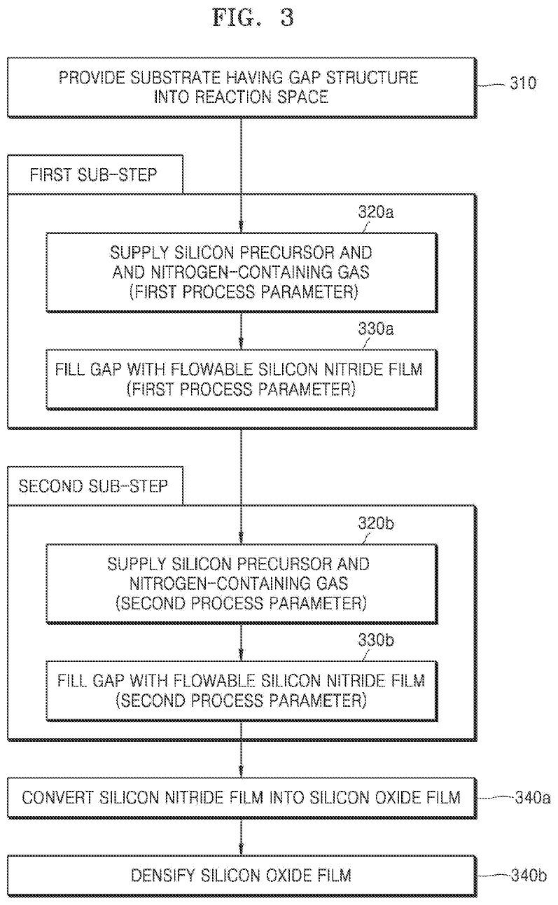

FIG. 2 is a flowchart illustrating a substrate processing method according to an exemplary embodiments of the present disclosure.

Referring to FIG. 2, a substrate is provided to a reaction space 210. The reaction space may include, for example, a reaction chamber in which a semiconductor manufacturing process may be performed. The substrate may include various substrates on which a flowable silicon nitride film, which may be formed according to an exemplary embodiment of the present disclosure, may be formed. A surface of the substrate on which the silicon nitride film may be formed may be formed of a single material, such as a conductive material, an insulating material, or a semiconductor material or may be formed of two or more different materials. In addition, a geometric structure of the surface of the substrate on which the silicon nitride film may be formed may be modified in various ways. For example, the surface of the substrate may include a flat surface parallel to a horizontal plane or may include a surface inclined at a constant angle with respect to the horizontal plane. In addition, the surface of the substrate may be convex or concave on a horizontal plane.

As described below, the silicon nitride film formed on the substrate has flowability, and a flow direction of the silicon nitride film may be closely related to a direction of force applied to the silicon nitride film. For example, the flow direction of the silicon nitride film is a direction in which gravity acts when the gravity acts on the silicon nitride film, and thus, when the surface of the substrate is convex, the silicon nitride film may be formed while flowing from the convex portion toward a circumference thereof. In addition, when the surface of the substrate is recessed and concave from a horizontal plane, a flowable silicon nitride film may be formed while flowing toward a concave portion. When the surface of the substrate is concave during a manufacturing process of a semiconductor device, the substrate may have, for example, a gap structure, a via structure, or a step structure.

The substrate provided during step 210 may have the gap structure. It should be noted that the gap structure is not limited to a general gap structure formed in a surface of a semiconductor device. That is, a substrate to which the present exemplary embodiments is applicable may have a structure having various types of recess regions or concave regions in which a silicon nitride film may be intensively filled while flowing under the influence of gravity when a flowable silicon nitride film is formed on the substrate. Specifically, a structure having a recess region or a concave region may include, for example, a general gap structure such as shallow trench isolation (STI) in a manufacturing process of a semiconductor device, a via structure penetrating an insulating layer to connect conductive layers to each other in a conductive layer/insulating layer/conductive layer structure; a via structure penetrating a conductive layer to connect insulating layers to each other in the insulating layer/conductive layer/insulating layer structure, and a step structure having a step shape in a depth direction from a surface. Hereinafter, application of exemplary embodiments of the present disclosure to a substrate having a gap structure will be described on behalf of a structure having a recess region or a concave region.

Referring to FIG. 2, a silicon precursor and a nitrogen-containing gas are supplied into a reaction space including a substrate therein 220. When a molecular structure of the supplied silicon source is too simple, for example, when a molecule is a monomer or a single molecule, a vapor pressure increases and a source easily volatilizes, and thus, flowability is reduced. On the other hand, when the molecular structure of the silicon source is a complex polymer, a molecular weight increases and a vapor pressure decreases to reduce flowability of a silicon source, and thus, a process efficiency is reduced during a process requiring a flowability having an appropriate flowability or more. For example, when a flowable film is used to fill a gap, a void may be formed in a gap when the flowable film has insufficient flowability. Therefore, an oligomeric silicon source having a molecular structure that is not too simple or not too complicated, for example, a chain structure of 2 to about 10 chains may be used as a silicon precursor used in exemplary embodiments of the present disclosure. For example, the oligomeric silicon source may include dimer-TSA, trimer-TSA, tetramer-TSA, pentamer-TSA, hexa mer-TSA, he pta mer-TSA, octa mer-TSA, and so on.

In some embodiments, the oligomeric silicon source may be supplied alone to a reaction space, and for example, dimer-TSA may be supplied alone as a silicon source to the reaction space, and in another embodiment, trimer-TSA may be supplied alone as a silicon precursor source. In addition, in some embodiments, two or more types of silicon precursor sources may also be supplied together. For example, in some embodiments, dimer-TSA and trimer-TSA may be simultaneously supplied as a silicon precursor source, and in another embodiment, trimer-TSA and tetramer-TSA may be simultaneously supplied as a silicon precursor source, and in another embodiment, dimer-TSA, trimer-TSA, and tetramer-TSA may be simultaneously supplied as a silicon precursor source.

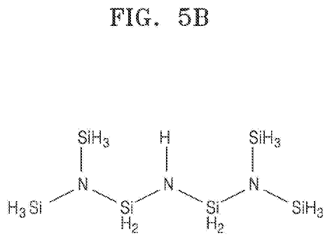

FIG. 5A illustrates a molecular structure of dimer-TSA in which two monomer-TSAs are bonded to each other, and FIG. 5B illustrates a molecular structure of trimer-TSA in which three monomer-TSAs are bonded to each other or monomer-TSA is bonded to dimer-TSA.

In addition, the nitrogen-containing gas used in the exemplary embodiments of the present disclosure may include at least one selected from N₂, N₂O, NO₂, NH₃, N₂H₂, N₂H₄, at least one of radicals thereof, and at least one of mixtures thereof. In some embodiments, NH 3 may be used as the nitrogen-containing gas. The nitrogen-containing gas may serve to promote a condensation reaction and cross-linking in an oligomerization process of an oligomeric silicon precursor.

Referring back to FIG. 2, a flowable silicon nitride film is formed on a substrate 230. A temperature of the substrate in a reaction space may be maintained at, for example, about 100° C. or less, preferably about 30° C. to about 70° C. Alternatively, a temperature of a silicon precursor source vessel may also be maintained at, for example, about 100° C. or less, preferably between about 30° C. and about 70° C. Then, radio frequency (RF) power of about 100 W to about 500 W, preferably about 200 W to about 400 W may be applied to the inside of the reaction space to generate a plasma state in the reaction space. In this case, an RF frequency to be used may be about 13 MHz to about 60 MHz, preferably about 20 MHz to about 30 MHz. In order to generate a plasma state in the reaction space, in exemplary embodiments of the present disclosure, RF power may be directly applied to a reaction space while supplying a silicon precursor source and a nitrogen-containing gas together to the reaction space, and thus, in-situ plasma treatment for generating plasma on a substrate may be used.

The oligomeric silicon precursor supplied into the reaction space together with the nitrogen-containing gas may flow with flowability on a substrate by thermal energy supplied to the substrate through a heating block on which the substrate may be mounted in the reaction space in a plasma state, and thus, a flowable silicon nitride film may be formed on the substrate. In this case, a temperature of the substrate is maintained at a relatively low temperature, for example, about 100° C. or less, preferably between about 30° C. and about 70° C., such that a silicon source may have a proper flowability. As described above, when a monomer or a silicon precursor source of single molecule is supplied onto a substrate maintained in such a temperature range, the silicon precursor source easily volatilizes to reduce flowability, and in contrast to this, when a silicon precursor source of polymer having a complex molecular structure is supplied, the silicon precursor source may not have meaningful flowability. Therefore, an oligomeric silicon precursor source having a molecular structure that is not too simple or too complex, for example, a chain structure of about 2 to about 10 chains may be used to have meaningful and suitable flowability for a semiconductor manufacturing process on the substrate in the range of substrate temperature.

An oligomeric silicon precursor source supplied on a substrate may flow on the substrate and form a structure having about 10 chain structures while oligomeric precursor source molecules may combine with each other when the oligomeric silicon precursor source flows. This is referred to as oligomerization. The oligomerization may be promoted through condensation between oligomer source molecules. During the condensation, hydrogen may be removed as a reaction byproduct at Si—H bond of the silicon precursor source. Oligomers bonded to each other through the condensation may have flowability and form a cross-linking structure through cross-linking while flowing in a silicon nitride film.

Subsequently, post-treatment may be performed on the silicon nitride film formed on the substrate 240. The post-treatment may include densification of a surface of the silicon nitride film. In another example, the post-treatment may include conversion of the silicon nitride film into a silicon oxide film. In a further example, the post-treatment may further include densification of the silicon oxide film converted from the silicon nitride film.

The post-treatment may be performed in various ways, for example, plasma treatment, ultraviolet (UV) treatment, or rapid thermal process (RTP). Optionally, when the post-treatment is a plasma treatment, the plasma treatment may be performed in an in-situ plasma treatment in which plasma is generated on a substrate while supplying a helium or argon gas.

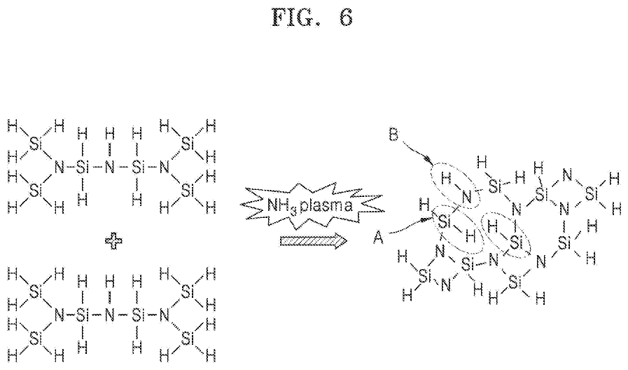

FIG. 6 is a diagram illustrating an example of a molecular structure reaction formula applicable to a substrate processing method, according to an exemplary embodiment of the present disclosure. That is, FIG. 6 illustrates a process of forming a silicon nitride film with a cross-linking structure while trimer-TSA supplied as a silicon precursor source flows on a surface of a substrate and two trimer-TSAs undergo condensation and cross-linking under an NH₃ plasma condition.

In addition, as described above, the nitrogen-containing gas used in the exemplary embodiments of the present disclosure may include at least one selected from N₂, N₂O, NO₂, NH₃, N₂H₂, N₂H₄, at least one of radicals thereof, and at least one of mixtures thereof. The nitrogen-containing gas may serve to promote cross-linking during an oligomerization process.

In a silicon nitride film structure of the cross-linking structure illustrated on the right of FIG. 6, a Si—H non-bond structure (Si—H dangling bond, for example, a portion A of FIG. 6) may exist in the cross-linking structure including an Si—N chain bonding structure, or an N-H non-bond structure (N-H dangling bond), for example, a portion B of FIG. 6 may exist in the Si—N cross-linking structure. In this case, pores may be formed in the cross-linking structure.

A bond structure of the silicon nitride film may be in an incomplete shape due to the pores. In other words, when the condensation and cross-linking are not sufficiently performed, pores may be formed, and as a result, a high-quality silicon nitride film may not be formed.

Formation of the pores may cause a problem particularly in a gap-fill process on a gap such as a recess or a trench having a narrow width of 20 nm or less. A deep portion (that is, a lower region) of the gap may have relatively little effect of plasma, and thus, pores may be easily formed. Furthermore, a shallow portion (that is, an upper region) of the gap may have relatively great effect of plasma, and thus, pores may not be formed, but polymerization may occur due to relatively strong plasma effect.

A difference in properties of a thin film depending on the height may occur when a gap-fill process is performed by using a direct plasma method of generating plasma by directly applying a voltage on a substrate, which may cause a problem in processes. For example, when a step of converting a silicon nitride film into a silicon oxide film is performed as the post-treatment process described above, a silicon nitride film formed in lower region of the gap may not be effectively and uniformly converted into a silicon oxide film due to pores generated therein, and a silicon nitride film formed in an upper region of the gap may not be effectively and uniformly converted into a silicon oxide film due to polymerization.

According to embodiments of the technical idea of the present disclosure, a plurality of sub-steps may be performed during the step 220 of supplying the silicon precursor and the nitrogen-containing gas and the step 230 of filling the silicon nitride film, and different process parameters may be applied during the plurality of sub-steps. Application of the different process parameters is to prevent a variation in material properties of a gap-fill layer depending on heights of a gap to be filled.

For example, in a first half of a gap-fill process, a first sub-step of supplying a silicon precursor and a nitrogen-containing gas and filling a silicon nitride film in a lower region of the gap may be performed by applying a first process parameter to prevent pores from being formed, and in a second half of the gap-fill process, a second sub-step of supplying a silicon precursor and a nitrogen-containing gas and filling a silicon nitride film in an upper region of the gap may be performed by applying a second process parameter to prevent polymerization.

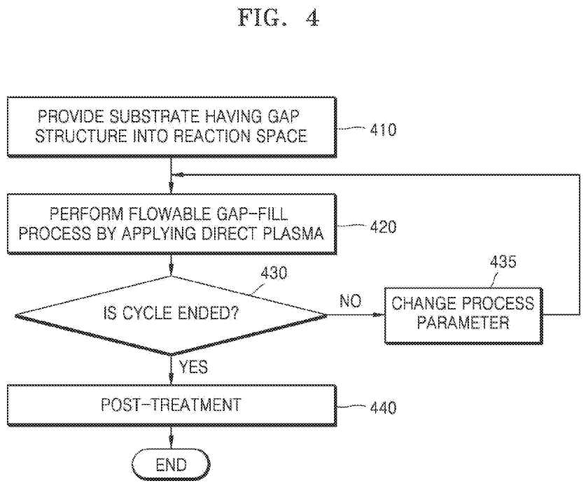

FIG. 3 is a flowchart schematically illustrating a substrate processing method according to an embodiment according to the technical idea of the present disclosure. The substrate processing method according to the embodiment may be a modification example of the substrate processing methods according to the embodiment described above. Hereinafter, redundant descriptions thereof are omitted.

Referring to FIG. 3, a substrate having a gap structure may be provided into a reaction space 310. A gap is formed in the substrate, and the substrate may be loaded onto a substrate support unit. Thereafter, a gap-fill process may be performed on the substrate on the substrate support unit. During the gap-fill process, a silicon precursor and a nitrogen-containing gas may be supplied into a reaction space 320a and 320b, and a silicon nitride film may be formed to fill the gap 330a and 330b.

More specifically, an oligomeric silicon precursor and a nitrogen-containing gas may be supplied onto the substrate through a gas supply unit on the substrate support unit. In addition, a RF power may be applied to at least one of the substrate support unit and the gas supply unit to generate plasma directly in the reaction space. Due to the plasma generated directly, the nitrogen-containing gas may be ionized to promote cross-linking of the oligomeric silicon precursor, and as a result, a flowable silicon nitride film that fills the gap may be formed.

In some embodiments, the step of supplying a precursor and/or a gas and the step of generating a plasma directly described above may be performed simultaneously. In addition, the step of supplying a precursor and/or a gas and the step of generating a plasma directly described above may be performed over a plurality of sub-steps in which different process parameters are set.

For example, during the first sub-step, step 320a of supplying a silicon precursor and a nitrogen-containing gas may be performed under a first process parameter, and step 330a of forming a flowable silicon nitride film in a gap by generating plasma under the first process parameter may be performed. The first sub-step may include a process for filling a lower region of the gap. Accordingly, the silicon nitride film formed during the first sub-step may constitute a lower portion of the entire silicon nitride film.

As described above, a deep portion (that is, the lower region) of the gap has relatively little effect of plasma, and thus, pores are easily formed. Accordingly, during the first sub-step, the first process parameter may be set to prevent pores from being formed in a film filling a gap. For example, the first process parameter may be set to increase an effect of plasma.

The second sub-step may be performed after the first sub-step, and during the second sub-step, step 320b of supplying a silicon precursor and a nitrogen-containing gas under the second process parameter may be performed, and step 330b of forming a flowable silicon nitride film in the gap by generating plasma under the second process parameter may be performed. This second sub-step may include a process for filling an upper region of the gap. Accordingly, the silicon nitride film formed during the second sub-step may constitute an upper region of the entire silicon nitride film.

As described above, the upper region of the gap has relatively great effect of plasma, and thus, polymerization of a film therein easily occurs. Accordingly, during the second sub-step, the second process parameter may be set to prevent polymerization of a film formed in the upper region of the gap. For example, the second process parameter may be set to reduce an effect of plasma.

The effect of plasma on a film filling a gap may be controlled by changing process parameters in Table 1 below.

TABLE 1
Plasma effects on film according to
the change of process parameters

| | Increased plasma | Decreased plasma |
|---|---|---|
| Process parameters | effect | effect |
| Power intensity | Increase | Decrease |
| Activated gas type | Light inert gas | Heavy inert gas |
| | (for example, He) | (for example, Ar) |
| Pressure | Decrease | Increase |
| Silicon precursor flow rate | Decrease | Increase |
| Nitrogen-containing gas | Increase | Decrease |
| flow rate | | |

As illustrated in the table above, as power (e.g. RF power), increases, an effect of plasma may increase, and as power decreases, the effect of plasma may decrease. As power increases, the effect of plasma increases to increase cross-linking efficiency of an oligomer, and as a result, a dense film may be formed to prevent pores from being formed.

In addition, during a plasma generation step, as an atomic number of inert gas supplied decreases, the effect of plasma may increase, and as the atomic number increases, the effect of plasma may decrease. For example, when plasma is generated by supplying a relatively light helium gas, penetration of active species into a film may increase and ion-bombardment effect may increase accordingly, and thus, a denser film may be formed.

In addition, as a pressure decreases, the effect of plasma may increase, and as a pressure increases, the effect of plasma may decrease. By maintaining a low pressure during generation of plasma, mobility of helium or argon active species may increase, and consequently, as the effect of plasma increases, density of a film may increase, and thus, pores may be prevented from being formed.

Additionally, as a flow rate of a silicon precursor decreases at the initial stage, e.g. a first sub-step, a film growth rate, that is, a gap-filling rate may be low. Therefore a plasma exposure time of the film per unit depth (or unit thickness) in the lower region of the gap may increase. In other words, the effect of plasma on the silicon nitride film filling the low region of the gap may increase and a dense silicon nitride film may be formed in the lower region of the gap. On the other hand, as the flow rate of a silicon precursor increases as the number of sub-steps increases, a film growth rate, that is, a gap-filling rate may be high. Therefore a plasma exposure time of the film per unit depth (or unit thickness) in the upper region of the gap may decrease compared to the film in the low region of the gap. That may result in a dense silicon nitride film with uniform film density from the upper region to the lower region of the gap, without generating pores.

Finally, as a flow rate of nitrogen-containing gas increases, radicals of the nitrogen-containing gas may increase during the plasma generation step, and as a result, condensation and cross-linking may be promoted in an oligomerization process of an oligomerization silicon precursor. Accordingly, a dense silicon nitride film, in which pores are prevented from being formed, may be formed.

By controlling at least one of the five process parameters described above, the effect of plasma may be controlled for each position of gaps, and thus, a film having a uniform film quality across the entire depth of the gap may be formed by preventing pores from being formed in a lower region of a gap and by preventing polymerization in an upper region of the gap.

An embodiment of individually controlling one of five process parameters is described with reference again to FIG. 3. It will be understood that the embodiments are examples and a plurality of process parameters may be adjusted. First, first RF power may be applied during the first sub-step, and second RF power less than the first RF power may be applied during the second sub-step.

In some other embodiments, plasma may be generated by using a light inert gas during the first sub-step, and plasma may be generated by using a heavy inert gas during the second sub-step. For example, argon plasma and helium plasma may be generated during a step of generating a direct plasma, in which case a ratio of the argon plasma to the helium plasma during the first sub-step may be less than a ratio of the argon plasma to the helium plasma during the second sub-step. That is, light helium radicals may be generated more than heavy argon radicals during the first sub-step, and the heavy argon radicals may be generated more than the light helium radicals during the second sub-step.

In still some other embodiments, a reaction space may be maintained at a first pressure during the first sub-step, and the reaction space may be maintained at a second pressure higher than the first pressure during the second sub-step. By maintaining the first pressure lower than the second pressure at the first sub-step, an average travel distance of radicals increases such that a reactant gas may reach deep to a lower region of a gap, and thus, efficiency of filling the lower region of the gap may be increased.

In addition, a flow rate of an oligomeric silicon precursor supplied during the first sub-step may be less than a flow rate of an oligomeric silicon precursor supplied during the second sub-step. By supplying a flow rate of the oligomeric silicon precursor supplied during the first sub-step, which is less than a flow rate of the oligomeric silicon precursor supplied during the second sub-step, the plasma exposure time of the silicon source layer per unit thickness may be longer during the first sub-step, and thus, densification of a film may increase. In addition, a flow rate of a nitrogen-containing gas supplied during the first sub-step may be greater than a flow rate of a nitrogen-containing gas supplied during the second sub-step. Accordingly, formation of a silicon nitride film in a lower region of a gap may be promoted.

After the first sub-step and the second sub-step are performed, the post-treatment steps 340a and 340b may be performed. For example, the step 340a of converting a silicon nitride film formed during the first sub-step and the second sub-step into a silicon oxide film may be performed. The conversion step may be performed through, for example, plasma treatment of a silicon nitride film.

In some embodiments, the plasma treatment in the conversion step 340a may be performed by supplying a remotely-activated oxygen in contrast to using direct plasma during the first sub-step and the second sub-step. In addition, the plasma treatment may be performed by ex-situ plasma treatment. In other words, while a gap-fill process is performed by in-situ plasma treatment for directly generating plasma on a substrate during the first sub-step and the second sub-step, the step 340a of converting a silicon nitride film into a silicon oxide film may be performed by ex-situ plasma treatment of supplying oxygen plasma to the substrate through a gas supply unit.

In some embodiments, the step 340a of converting the silicon nitride film into a silicon oxide film may be performed at a relatively high temperature. Specifically, a plurality of sub-steps of forming a silicon nitride film, such as the first sub-step and the second sub-step, may be performed at a first temperature, and the step 340a of converting a film may be performed at a second temperature higher than the first temperature.

The silicon oxide film formed during the step 340a of converting a film may have an oxygen concentration within a preset deviation throughout the silicon oxide film filling the gap. The oxygen concentration within the preset deviation is due to the plurality of sub-steps to which different process parameters are applied. In other words, because a silicon nitride film having a uniform film quality may be formed throughout the gap, a high-quality silicon oxide film having a uniform oxygen concentration may be formed after the subsequent step 340a of converting a film.

In an optional embodiment, after the step 340a of converting a film, step 340b of densifying a silicon oxide film may be performed. Densification may be performed in various ways, for example, plasma treatment, UV treatment, or a rapid thermal process (RTP). The densification may be performed under an oxygen atmosphere and may be performed at a relatively high temperature. For example, a plurality of sub-steps, e.g. 220 and 230, may be performed at the first temperature, the step 340a of converting a film may be performed at the second temperature higher than the first temperature, and the step 340b of densifying a film may be performed at a third temperature higher than the second temperature.

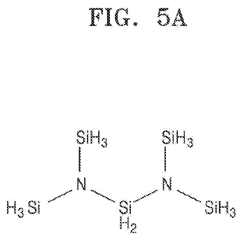

FIG. 4 is a flowchart schematically illustrating a substrate processing method according to an embodiment of the technical idea of the present disclosure. The substrate processing methods according to the embodiments may be modification examples of the substrate processing methods according to the embodiments described above. Hereinafter, redundant descriptions of the embodiments are omitted.

Referring to FIG. 4, in order to process a substrate in which a gap is formed, the substrate is first loaded onto a substrate support unit 410. Thereafter, a flowable gap-fill process may be performed by applying a direct plasma 420. The flowable gap-fill process may be performed by repeating a cycle, and process parameters used for the flowable gap-fill process may be changed while the cycle is repeated 435. In other words, the flowable gap-fill process may be performed in which a plurality of sub-steps to which different process parameters are applied are repeated.

More specifically, the flowable gap-fill process for partially filling a gap may be performed as a first sub-step, and after process parameters are changed, a flowable gap-fill process for additionally filling the gap may be performed as a second sub-step. After the flowable gap-fill process, whether the cycle is finished may be determined 430, and when it is determined that the cycle is finished (that is, when the gap is completely filled), a post-treatment process 440 for the gap-fill film may be performed.

As described above, when a flowable gap-fill process of filling a gap having a width of 20 nm or less is performed by using an oligomer source in a direct plasma method, there may be a difference in film properties depending on the depth of a gap. According to embodiments of the technical idea of the present disclosure, the flowable gap-fill process may be performed over a plurality of sub-steps, and process parameters may be changed while repeating the sub-steps. In other words, during a gap-fill process, process parameters may not be fixed but sequentially changed. For example, during the gap-fill process, the process parameters may be changed continuously or stepwise. Through this, there is a technical effect that, in filling a narrow gap, a variation in film properties depending on depths of gaps may be reduced.

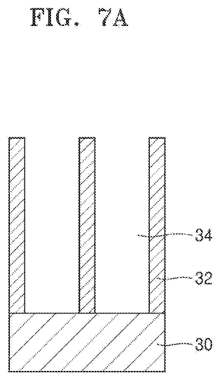

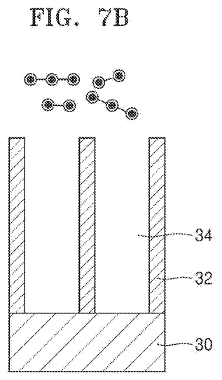

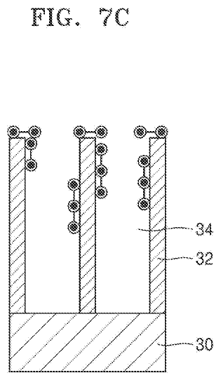

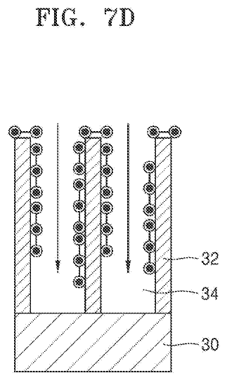

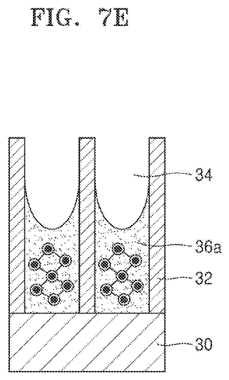

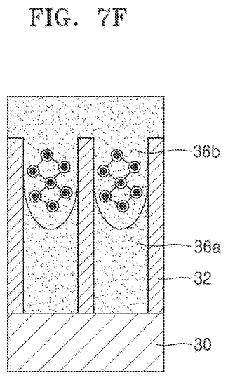

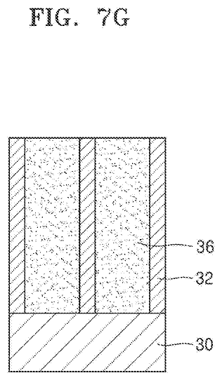

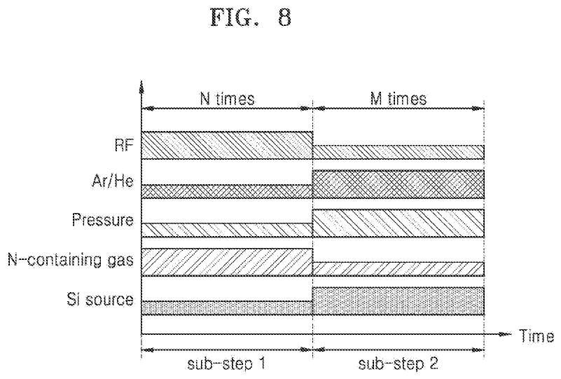

FIGS. 7A to 7G are cross-sectional views illustrating in process sequence a gap-fill process according to exemplary embodiments of the technical idea of the present disclosure. In addition, FIG. 8 illustrates exemplary process parameters for performing the gap-fill process of FIGS. 7A to 7G.

Referring to FIG. 7A, a substrate is provided to a reaction space (not illustrated) in which a gap-fill process may be performed. A gap structure, which may include a gap 34 having a certain depth in a vertical direction and a certain width in a horizontal direction in some region of a surface of a substrate 30, is illustrated. The gap 34 may have a width of 20 nm or less. The substrate may include a semiconductor material such as Si or Ge, various compound semiconductor materials such as SiGe, SiC, GaAs, InAs, and InP, and various substrates used in semiconductor devices and display devices, such as silicon on insulator (501) and silicon on sapphire (SOS).

The gap 34 may include not only shallow trench isolation (STI) commonly used to define active regions in semiconductor manufacturing processes, and recess regions of various shapes formed in a surface of the substrate 30. In addition, the gap 34 may also have a form of a via that penetrates a conductive layer between insulating layers or penetrating an insulating layer between conductive layers. The gap 34 in FIG. 7A illustrates the gap 34 having a shape formed by partially etching a material layer 32 formed on a surface of the substrate 30. The material layer 32 may be formed of, for example, a conductive material, an insulating material, or a semiconductor material.

In addition, the material layer 32 is illustrated as a single layer but may consist of multiple layers. In addition, the gap 34 may be formed in a cylindrical shape, and a cross-sectional shape of a surface of the gap 34 may include various polygons, such as an oval, a triangle, a square, a pentagon, and a circle. In addition, the gap 34 may be formed in an island shape including various surface cross-sectional shapes, but the gap 34 may also be formed in a line shape on the substrate 20. In addition, the gap 34 may have a vertical profile having approximately the same width from an upper region (e.g. an entrance region of the gap 34) to a lower region. However, the gap 34 may also have a non-vertical profile that decreases or increases linearly or stepwise in width from an upper region of a gap to a lower region thereof. In another example, the gap 34 may have a width in some regions of the gap that is greater or less than a width in the upper region of the gap.

In addition, although FIG. 7A illustrates a gap structure in the form of the material layer 32 formed of a material different from a material of the substrate 30 on the substrate 30, but an STI structure may have a gap formed in a substrate itself. Accordingly, in the present specification, a “substrate” may simply refer to the substrate 30 or may refer to a substrate having various surface structures before forming a flowable film according to the present disclosure, for example, a flowable silicon nitride film may be formed thereon.

Referring to FIG. 7B, a silicon precursor and a nitrogen-containing gas are supplied onto the substrate 30 on which the gap structure may be formed in a reaction space in which a gap-fill process may be performed. FIG. 7B illustrates an oligomerization process of a silicon precursor source together with supply of the silicon precursor and the nitrogen-containing gas. The silicon precursor used in the exemplary embodiments of the present disclosure may include an oligomeric silicon precursor source having a molecular structure that is not too simple or not too complex, for example, a chain structure of about 2 to about 10 chains. For example, the oligomeric silicon source may include dimer-TSA, trimer-TSA, tetramer-TSA, pentamer-TSA, hexamer-TSA, heptamer-TSA, octamer-TSA, and so on.

In some embodiments, the oligomeric silicon source may be supplied alone to a reaction space, and for example, dimer-TSA may be supplied alone as a silicon precursor source to the reaction space, and in another embodiment, trimer-TSA may be supplied alone as the silicon precursor source. In addition, in some embodiments, two or more types of silicon precursor sources may also be supplied together. In some embodiments, dimer-TSA and trimer-TSA may be simultaneously supplied as a silicon precursor source, and in another embodiment, trimer-TSA and tetramer-TSA may be simultaneously supplied as a silicon precursor source, and in another embodiment, dimer-TSA, trimer-TSA, and tetramer-TSA may be simultaneously supplied as a silicon precursor source.

FIG. 7B illustrates that, for example, dimer-TSA and trimer-TSA are simultaneously supplied as a silicon precursor source. In addition, an oligomeric silicon precursor source previously synthesized to have about 2 to about 10 chain structures may be supplied into a reaction space, and an oligomeric silicon precursor source having a small chain structure may also be formed in a structure including about 10 chain structures through oligomerization reaction and condensation reaction while flowing on the exposed surface of the substrate.

In addition, the nitrogen-containing gas used in the exemplary embodiments of the present disclosure may include at least one selected from N₂, N₂O, NO₂, NH₃, N₂H₂, N₂H₄, at least one of radicals thereof, and at least one of mixtures thereof. In one embodiment, NH₃ may be used as the nitrogen-containing gas.

In addition, a temperature of the substrate in a reaction space may be maintained at, for example, about 100° C. or less, preferably about 30° C. to about 70° C. A process temperature in the reaction space or a vessel temperature of the silicon precursor source may also be maintained at or below, for example, about 100° C., preferably about 30° C. to about 70° C. In addition, RF power of about 100 W to about 500 W, preferably about 200 W to about 400 W may be applied to the inside of the reaction space to cause the reaction space to be in a plasma state. In this case, an RF frequency to be used may be about 13 MHz to about 60 MHz, preferably about 20 MHz to about 30 MHz.

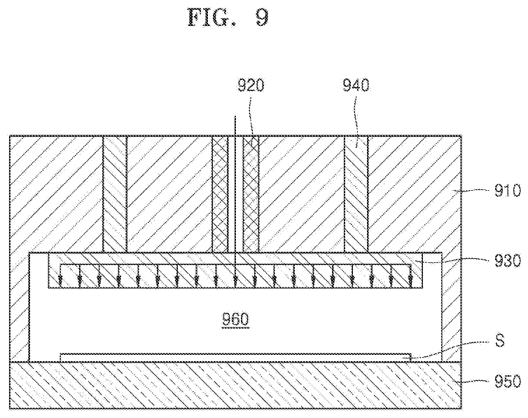

In order to cause the reaction space to be in a plasma state, in exemplary embodiments of the present disclosure, RF power may be directly applied to a reaction space while supplying a silicon precursor source and a nitrogen-containing gas together in the reaction space, and thus, in-situ direct plasma treatment for generating plasma on a substrate may be carried out. An example of a substrate processing apparatus used for the in-situ direct plasma treatment is illustrated in FIG. 9, and detailed descriptions of the substrate processing apparatus is described below.

FIG. 7C illustrates a process of causing a low polymerization reaction and condensation reaction between silicon precursor source molecules supplied into a reaction space. That is, the oligomeric silicon precursor supplied into the reaction space together with the nitrogen-containing gas may flow with flowability on an exposed surface of a substrate by thermal energy supplied to the substrate through a heating block on which a substrate may be mounted in the reaction space in a plasma state, and as the oligomeric silicon precursor source flows on the substrate, oligomeric precursor source molecules combine with each other, and thus, a structure including about 10 chain structures may be formed through an oligomerization reaction and a condensation reaction.

Referring to FIG. 7D, flowable oligomers flow toward a lower region of the gap 34 under the influence of gravity along the exposed surface of the substrate 30 having the gap 34 formed thereon and the exposed surface of the gap 34. By filling a gap with flowable oligomers as described above, the gap may be filled without a void or a seam.

Referring to FIG. 7E, flowable oligomers continuously move toward a lower region of the gap 34 along the exposed surface of the gap 34, and thus, a silicon nitride film 36a may partially fill the gap 34 from the lower region of the gap 34 in a bottom-up filling manner. In this case, the silicon nitride film 36a filled in the gap 34 may have a cross-linking structure of a ring shape as illustrated in FIG. 6 by cross-linking. The silicon nitride film 36a formed in FIG. 7E is defined as a first silicon nitride film.

Referring to FIG. 7F, a silicon nitride film 36b may additionally be filled on the silicon nitride film 36a that is previously at least partially filled in the gap 34. The silicon nitride film 36b formed in FIG. 7F is defined as a second silicon nitride film. As described above, filling of the second silicon nitride film 36b may be performed under different process conditions from filling of the first silicon nitride film 36a. More specifically, filling of the first and second silicon nitride films 36a and 36b may be equally performed in that direct plasma is applied in a flowable gap-fill process, and the first and second silicon nitride films 36a and 36b may have the same condition in some process parameters (for example, a temperature) but may have different process parameters in at least one of RF power, a type of gas activated by RF power, a pressure, a flow rate of a silicon precursor, and a flow rate of a nitrogen-containing gas.

For example, as illustrated in FIG. 8, during the first sub-step of forming the first silicon nitride film 36a in a lower region of a gap where micropores are easily formed due to relatively small influence of plasma, a pressure of a reaction space may be maintained at a first pressure, and an oligomeric silicon precursor at a first flow rate may be supplied in a state in which the first RF power may be applied. In addition, during the second sub-step of forming the second silicon nitride film 36b in an upper region of the gap where polymerization is easily performed due to relatively great influence of plasma, the pressure of the reaction space may be maintained at a second pressure higher than the first pressure, and an oligomeric silicon precursor at a second flow rate greater than the first flow rate may be supplied in a state in which a second RF power less than the first RF power may be applied.

In addition, a ratio of a flow rate of argon (Ar) to a flow rate of helium (He) in the first sub-step of FIG. 8 may be less than a ratio of a flow rate of argon (Ar) to a flow rate of helium (He) in the second sub-step. That is, the flow rate of argon supplied in the first sub-step may be less than the flow rate of argon supplied in the second sub-step, and the flow rate of helium supplied in the first sub-step may be greater than the flow rate of helium supplied in the second sub-step.

In addition, a flow rate of a nitrogen-containing gas supplied in the first sub-step of FIG. 8 may be greater than a flow rate of a nitrogen-containing gas supplied in the second sub-step.

Optionally, in some embodiments, while forming the silicon nitride films 36a and 36b, the flow rates of Ar gas, He gas, and nitrogen-containing gas may be maintained the same.

In some embodiments, as illustrated in FIG. 8, the first sub-step and the second sub-step may be repeated respectively N times and M times. In addition, although not illustrated in the drawings, a sub-step having different process parameter conditions may be additionally performed before the first sub-step, between the first sub-step and the second sub-step, or after the second sub-step.

Referring to FIG. 7G, a post-treatment may be performed on the inside of the gap 34, and a surface may be planarized by, for example, an etch-back process such that an upper surface of the material layer 32 may be exposed. The post-treatment may include a step of densifying, for example, the first and second silicon nitride films 36a and 36b. In another example, the post-treatment may include a step of converting the first and second silicon nitride films 36a and 36b into silicon oxide films. In some examples, the step of conversion may be performed by applying a remote plasma method. Furthermore, the post-treatment may also further include a step of densifying a silicon oxide film.

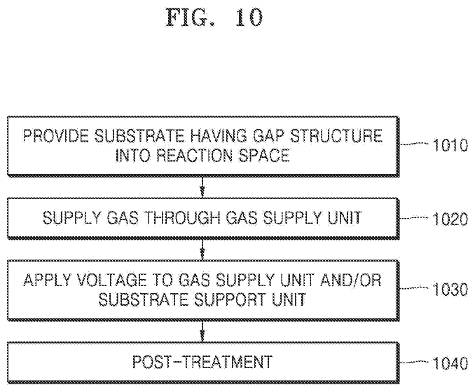

FIG. 9 schematically illustrates a substrate processing apparatus according to an embodiment of the technical idea of the present disclosure, and FIG. 10 is a flowchart schematically illustrating a substrate processing method using a substrate processing apparatus. The substrate processing methods according to the embodiments may be modification examples of the substrate processing methods according to the embodiments described above. Hereinafter, redundant descriptions thereof are omitted.

Referring to FIG. 9, a substrate processing apparatus may include a partition wall 910, a conduit 920, a gas supply unit 930, an RF rod 940, and a substrate support unit 950. Although an example of the substrate processing apparatus described herein may include a deposition apparatus for a semiconductor or display substrate, the present disclosure is not limited thereto.

The partition wall 910 may include a component of a reactor. In other words, a reaction space 960 for processing the substrate S (for example, gap-fill) may be formed by a partition wall structure. For example, the partition wall 910 may include at least one through-hole. A gas supply channel may be provided through a through-hole of the partition wall 910.

The conduit 920 may be in the partition wall 910 through the through-hole. The conduit 920 may include a gas supply channel of the substrate processing apparatus. When a deposition apparatus is an atomic layer deposition apparatus, a source gas, a purge gas, and/or a reaction gas may be supplied through the conduit 920. The conduit 920 may include an insulating material. In an alternative embodiment, the conduit 920 may include an insulating conduit formed of an insulating material.

The gas supply unit 930 may be connected to the conduit 920 that may include a gas supply channel. The gas supply unit 930 may be fixed to a reactor. For example, the gas supply unit 930 may be fixed to the partition wall 910 through a fixed member (not illustrated). The gas supply unit 930 may supply a gas to a substrate S in the reaction space 960. For example, the gas supply unit 930 may include a showerhead assembly configured to uniformly spray a gas.

The RF rod 940 may be connected to the gas supply unit 930 by penetrating at least a portion of the partition wall 910. The RF load 940 may be connected to an external power application unit (not illustrated). Although two RF rods 940 are illustrated in FIG. 2, the present disclosure is not limited thereto, and uniformity of plasma power supplied to the reaction space 960 may be increased by installing two or more RF rods. In addition, although not illustrated in the drawings, an insulator may be located between the RF rod 940 and the partition wall 910 to block an electrical connection between the RF rod 940 and the partition wall 910.

The gas supply unit 930 may include a conductor and may be used as an electrode for generating plasma. That is, as the gas supply unit 930 is connected to the RF rod 940, the gas supply unit 930 itself may act as one electrode for generating plasma. The gas supply unit 930 in this manner (a manner in which the gas supply unit 930 itself is used as an electrode) is hereinafter referred to as a gas supply electrode.

The substrate support unit 950 may provide a region in which the substrate S, such as a semiconductor or display substrate, is mounted. In addition, the substrate support unit 950 may be in contact with a lower surface of the partition wall 910. For example, the substrate support unit 950 may be supported by a support portion (not illustrated) capable of vertical and rotational movements. As the substrate support unit 950 is separated from or comes into contact with the partition wall 910 by the movement of the support portion, the reaction space 960 may be opened or closed. In addition, the substrate support unit 950 may include a conductor and may be used as an electrode (that is, a counter electrode of the gas supply electrode) for generating plasma.

A direct plasma method refers to a method of directly generating plasma on the substrate S in a reaction space by applying RF power through the gas supply unit 930 and/or the substrate support unit 950 acting as the electrode. FIG. 10 is a flowchart illustrating a gap-fill process using a direct plasma method and may be performed by using, for example, the substrate processing apparatus of FIG. 9.

Referring to FIG. 10, a substrate having a gap structure may be first provided into a reaction space, and then a gas may be supplied through a gas supply unit. After a gas is supplied through the gas supply unit or at the same time as the supply of the gas, a voltage may be applied to the gas supply unit and/or the substrate support unit, and thereby, a gap-fill process may be performed. After gap-fill is complete, a post-treatment step may be performed.

Steps of the gap-fill process illustrated in FIG. 10 correspond to the steps illustrated in FIGS. 2 and 3. Specifically, step 1020 of supplying a gas through the gas supply unit of FIG. 10 may correspond to the steps 220, 320a, and 320b of supplying the silicon precursor and the nitrogen-containing gas of FIGS. 2 and 3. In addition, step 1030 of applying a voltage to a gas supply unit and/or a substrate support unit in FIG. 10 may correspond to steps 230, 330a, and 330b of filling a gap with a flowable silicon nitride film in FIGS. 2 and 3. In addition, a post-treatment step 1040 of FIG. 10 may correspond to the post-treatment step 240 of FIG. 2 and the conversion step 340a and densification step 340b of FIG. 3. This means that the substrate processing method according to the embodiments of FIGS. 2 and 3 may be performed by operating the substrate processing apparatus of FIG. 9 according to the substrate processing method described with reference to FIG. 10.

When a deposition process is performed in a single step by using a chemical vapor deposition (CVD) apparatus in which a direct plasma method may be carried out, quality of an oligomer filled in a gap having a small critical dimension (CD) may change depending on the depth of the gap. The oligomers filled in a lower region of the gap may be affected by plasma for a short time and therefore be relatively poorly affected by plasma due to geometric feature of a gap structure, that is, a non-planar feature such as concave structure, and thus, a cross-linking efficiency may be reduced. In contrast to this, the oligomers filled in an upper region of the gap may be exposed to plasma for a long time as the upper region of the gap may be less concave. Therefore the oligomers filling the upper region of the gap may be directly affected by plasma generated around a substrate surface compared to the oligomers filling the lower region of the gap. As a result, the upper region of the gap may be easily polymerized, which may lead to an increase in density.

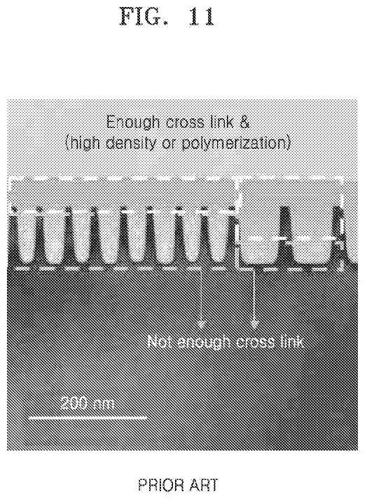

The above phenomenon may be easily found in FIG. 11 illustrating a transmission electron microscope (TEM) image for comparing CDs after single-step deposition is performed on a pattern having various CDs. Referring to FIG. 11, a narrow CD gap has a smaller volume than a wide CD gap, and therefore, the gap is fully filled only with the oligomers generated at the beginning of a CVD process, and a depth affected by plasma is also less than a depth affected by plasma in a wide CD gap. In contrast to this, the wide CD gap, which has a large volume of the gap, is filled with oligomers generated in the latter part of the gap-fill process having sufficient plasma effect, and therefore, deeper regions of the gap may be affected by plasma. For this reason, pores may be formed up to an upper region in a narrow CD gap, and pores may be formed in a relatively low region in a wide CD gap.

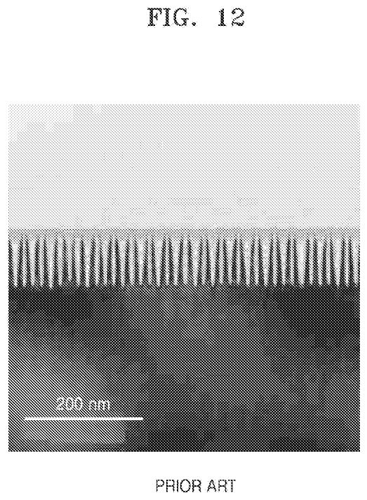

This means that, when deposition is performed on a pattern having a narrow CD size of about 10 nm to about 20 nm as illustrated in FIG. 12, pores may be formed over the pattern.

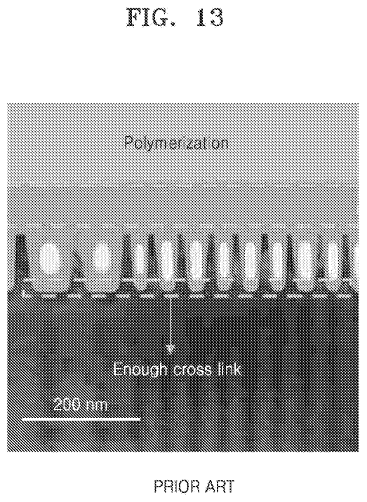

In order to prevent pores from being formed in a lower region of a gap, a helium plasma CVD gap-fill process may be carried out. Because a helium gas is lighter than an argon gas, helium radicals may move more deeply into the lower region of the gap than argon radicals and may increase polymerization, densification, and step coverage feature of a film in the lower region of the gap. However, when helium plasma with good ignition efficiency is processed for a certain period of time or longer in a flowable CVD gap-fill process using direct plasma, the lower region of the gap may be filled with a dense film without pores, but an upper region of the gap may be polymerized due to excessive plasma effect, resulting in formation of seams or pores. This phenomenon is illustrated in FIG. 13.

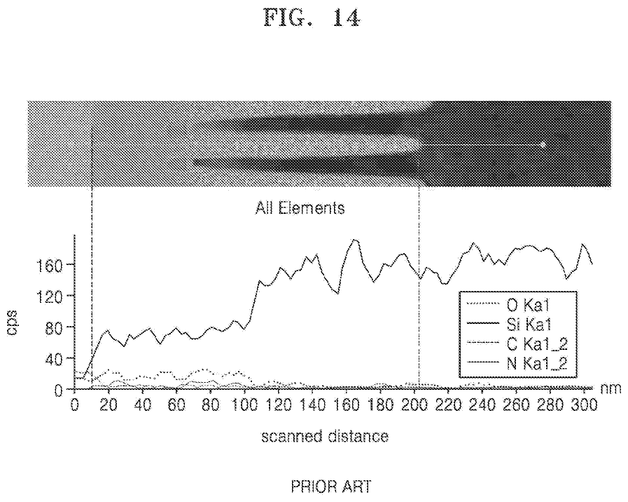

Even when suitable process conditions are found in which the film formed in the upper region of the gap is not polymerized and pores are not formed in the film formed in the lower region of the gap, in a case in which deposition is performed in a single-step process, it is difficult to prevent the non-uniform density gradient from the upper region of the gap to the lower region of the gap. A dense film on a pattern surface reduces an effect of remote oxygen plasma over the film filling the gap during a subsequent conversion step, and thereby, a silicon nitride film may be converted into a silicon oxide film mainly in the upper region of the gap, and the conversion may not be effectively performed in the lower region of the gap, resulting in non-uniform oxygen concentration depending on depths of the gap as shown in FIG. 14. FIG. 14 is an EDS (energy dispersive X-ray spectroscopy) analysis results showing a distribution of elements constituting a film depending on the depth of the gap. The parallel axis is a scanned distance and the vertical axis is a detecting count per unit time (CPS) of the element.

In the present disclosure, in order to reduce a difference in film properties and a conversion efficiency in the upper and lower regions of the gap which occurs when deposition is performed in a single step, a method of dividing a deposition process into several sections is proposed. In more detail, pores and density degradation in the lower region of the gap may be reduced and polymerization of oligomers in the upper region of the gap, which is a main cause of non-uniform conversion efficiency over the film filling the gap, may be reduced by changing the type of carrier gas, a pressure, RF power, and so on in each step.

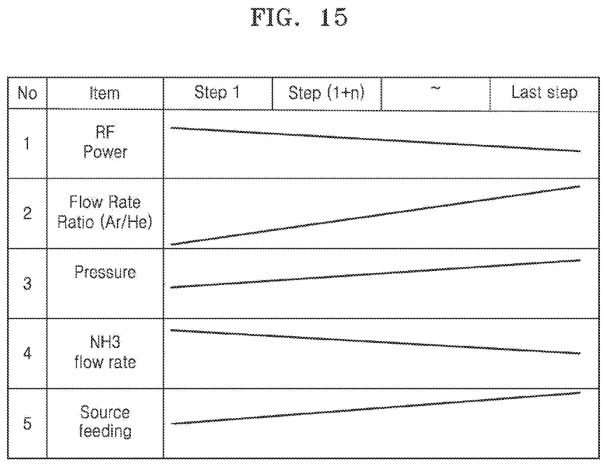

The deposition process may be divided into two or more steps, and the changed parameters may be applied to one or more of the following items (see FIG. 15).

1. RF Power: RF power may be reduced with an increase in the number of sub-steps—Cross-linking efficiency of oligomers increases in a lower region of a gap by applying high RF power at initial sub-step of in the process.

Polymerization in an upper region of the gap may be suppressed by low RF power in a subsequent step.

2. Argon/helium (Ar/He) flow ratio: With an increase in the number of sub-steps, a flow rate of helium may be reduced and a flow rate of argon may increase. In an initial sub-step, the flow rate of helium gas may be greater than the flow rate of argon gas. The helium gas is lighter than the argon gas, and the mobility and the linearity of helium radicals may be higher than the mobility and the linearity of argon radicals accordingly. Therefore, helium plasma may be stronger than argon plasma in intensity, and the helium radicals may move to a deeper region of the gap. In addition, when the helium plasma is supplied, a step coverage of a film may be improved an intensity of plasma may be maintained up to the lower region of the gap, and a cross-linking efficiency of oligomers may increase in the lower region of the gap.

In a subsequent sub-step, the flow rate of argon gas may be greater than the flow rate of helium gas. The argon gas is heavier than the helium gas and argon plasma may be weaker than helium plasma in intensity and mobility. Therefore, polymerization may be suppressed in the upper region of the gap by increasing the flow rate of argon in the subsequent sub-steps.

3. Pressure: Pressure may be increased with an increase in the number of sub-steps—Mobility of radicals may increase by maintaining a low process pressure in the initial step and increasing the mean free path of radicals. Accordingly, intensity of plasma may be strengthened, density of a film in the lower region of the gap may be increased and the non-uniformity of film density may be reduced over the gap.

In the subsequent sub-step, polymerization may be suppressed by increasing a process pressure. Increase of process pressure may shorten the mean free path of radicals, therefore the plasma effects (e.g. plasma intensity) to the film may be reduced and the polymerization of a film may be suppressed. In addition, a void phenomenon in which an entrance of a gap is first blocked and a void is formed therein may be prevented by suppressing the oligomerization in the upper region of the gap and improving the flowability of a film. Therefore, the penetration efficiency of the flowable film flowing into the gap may be improved throughout the subsequent sub-sections.

4. Flow rate of NH₃: A flow rate of NH₃ may be reduced with an increase in the number of sub-steps—Flow rate of NH₃ may be increased in the initial step to increase the cross-linking efficiency.

In a subsequent step, the flow rate of NH₃ may be reduced stepwise to increase the flowability and to reduce the film density.

5. Source feeding; A flow rate of a source gas may be increased with an increase in the number of sub-steps—The flow rate of the source gas may be reduced in the initial step to reduce a deposition rate and to increase an exposure time of a film to plasma in a lower region of a gap. The ratio of the flow rate of NH₃ to the flow rate of source gas may increase at initial sub-steps, therefore, a cross-linking efficiency may be increased in the lower region of the gap.

In a subsequent sub-step, the flow rate of the source gas may be increased to maintain uniform film density throughout the gap.

FIG. 15 illustrates that process parameters including a flow rate and an intensity are continuously changed throughout the sub-steps, but in an alternative embodiment, the flow rate and the intensity may be changed stepwise throughout the sub-steps. In FIG. 15, for example, RF power may decrease continuously and gradually from an initial step 1 to the a subsequent sub-step (step 1+n), but in an alternative embodiment, the RF power may be maintained constant in step 1 and may be maintained constant at lower power in a subsequent sub-step (step 1+n).

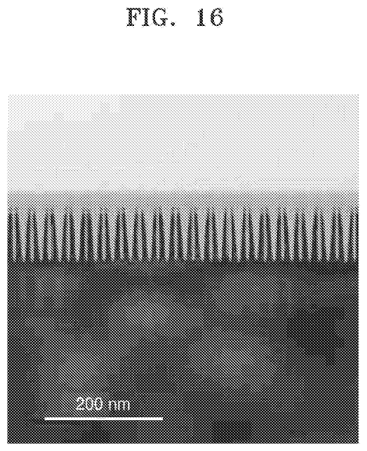

FIG. 16 illustrates that, pores are not formed at a lower portion of a gap and a uniform film is filled in the entire region of the gap without voids or seams caused by low flowability by applying a flowable gap-fill process including multiple steps as illustrated in FIG. 15 and described above.

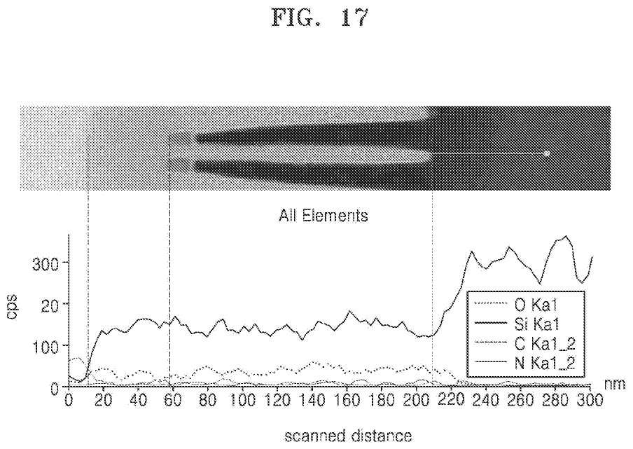

FIG. 17 illustrates an EDS analysis data. In FIG. 17, when a silicon nitride film is converted into a silicon oxide film, oxygen concentration is uniform in the entire film by reducing polymerization in an upper region of a gap through multiple steps as illustrated in FIG. 15 and described above.

It should be understood that shapes of respective portions in the accompanying drawings are examples to clearly understand the present disclosure. It should be noted that the shapes of the respective portions in the accompanying drawings may be modified in various other shapes.

Those skilled in the art to which the present disclosure pertains will clearly understand that the present disclosure described above is not limited to the embodiments described above and the accompanying drawings, and various substitutions, modifications, and changes may be made without departing from the technical idea of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of processing a substrate having a gap, the method comprising:
loading the substrate onto a substrate support unit;
supplying an oligomeric silicon precursor and a nitrogen-containing gas onto the substrate on the substrate support unit through a gas supply unit; and
generating a direct plasma in a reaction space by applying a voltage to at least one of the substrate support unit and the gas supply unit,
wherein a plurality of sub-steps are performed during the supplying of the oligomeric silicon precursor and the nitrogen-containing gas and the generating a direct plasma, and
different process parameters are applied during the plurality of sub-steps.

2. The method of claim 1, wherein a flowable silicon nitride film is formed on the substrate during the generating a direct plasma.

3. The method of claim 2, further comprising:
converting the silicon nitride film into a silicon oxide film.

4. The method of claim 3, wherein the plurality of sub-steps are performed at a first temperature and the converting is performed at a second temperature higher than the first temperature.

5. The method of claim 3, wherein, during the converting, the silicon oxide film has an oxygen concentration within a preset deviation across a depth of the gap, and the oxygen concentration within the preset deviation is caused by the plurality of sub-steps to which different process parameters are applied.

6. The method of claim 3, wherein the converting is performed by using remote oxygen plasma.

7. The method of claim 3, further comprising:
densifying the silicon oxide film.

8. The method of claim 7, wherein the plurality of sub-steps are performed at a first temperature, and the densifying is performed at a third temperature higher than the first temperature.

9. The method of claim 1, wherein the plurality of sub-steps comprises a first sub-step and a second sub-step subsequent to the first sub-step.

10. The method of claim 9, wherein a first process parameter is set to prevent pores from being formed in a film filling a gap during the first sub-step, and a second process parameter is set to prevent the film filling the gap from being polymerized during the second sub-step.

11. The method of claim 9, wherein a silicon nitride film for filling the gap is formed during the generating a direct plasma.

12. The method of claim 11, wherein
the silicon nitride film comprises a first portion and a second portion formed on the first portion, and
the first portion is formed by the first sub-step, and the second portion is formed by the second sub-step.

13. The method of claim 9, wherein first RF power is applied during the first sub-step, and second RF power less than the first RF power is applied during the second sub-step.

14. The method of claim 9, wherein
argon plasma and helium plasma are generated during the generating a direct plasma, and
a ratio of an argon gas to a helium gas during the first sub-step is less than a ratio of the argon gas to the helium gas during the second sub-step.

15. The method of claim 9, wherein the reaction space is maintained at a first pressure during the first sub-step, and the reaction space is maintained at a second pressure higher than the first pressure during the second sub-step.

16. The method of claim 9, wherein a flow rate of the oligomeric silicon precursor supplied during the first sub-step is less than a flow rate of the oligomeric silicon precursor supplied during the second sub-step.

17. The method of claim 9, wherein a flow rate of the nitrogen-containing gas supplied during the first sub-step is greater than a flow rate of the nitrogen-containing gas supplied during the second sub-step.

18. A method of processing a substrate having a gap formed on a surface of the substrate, the method comprising:
loading the substrate into a reaction space;
partially filling the gap by using a direct plasma method, by maintaining the reaction space at a first temperature of less than 100° C. and a first pressure, supplying an oligomeric silicon precursor at a first flow rate in a state in which first RF power is applied, and supplying a nitrogen-containing gas;
additionally filling the gap by using the direct plasma method, by maintaining the reaction space at the first temperature and a second pressure higher than the first pressure, supplying an oligomeric silicon precursor at a second flow rate greater than the first flow rate in a state in which second RF power less than the first RF power is applied, and supplying the nitrogen-containing gas;
converting, by using a remote plasma method, a flowable silicon nitride film formed in the gap of the substrate by partially filling the gap and additionally filling the gap into a silicon oxide film; and
densifying the silicon oxide film under an oxygen atmosphere.

19. The method of claim 18, wherein
the converting is performed at a second temperature higher than the first temperature, and
the densifying is performed at a third temperature higher than the second temperature.

20. A method of processing a substrate to fill a gap having a width of 20 nm or less included in the substrate by repeating a cycle, the cycle comprising:
performing a flowable gap-fill process by applying a direct plasma; and
changing a process parameter while performing the flowable gap-fill process.

21. The method of claim 18, wherein the oligomeric silicon precursor includes at least one selected from dimer-trisilylamine (TSA), trimer-TSA, tetramer-TSA, pentamer-TSA, hexamer-TSA, heptamer-TSA, octamer-TSA, and mixtures thereof.

22. The method of claim 18, wherein the nitrogen-containing gas includes at least one selected from N₂, N₂O, NO₂, NH₃, N₂H₂, N₂H₄, at least one of radicals thereof, and at least one of mixtures thereof.
